(19) United States
(12) Patent Application Publication
(10) Pub. No.: US 2005/0056855 A1
(43) Pub. Date: Mar. 17, 2005

(54) Light-emitting device with enlarged active light-emitting region

(76) Inventors: Ming-Der Lin, Hsinchu (TW); Jung-Kuei Hsu, Taipei (TW); San-Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/777,062

(22) Filed: Feb. 13, 2004

(30) Foreign Application Priority Data
Sep. 16, 2003 (TW) 092125533

(51) Int. Cl. H01L 27/15

(52) U.S. Cl. 257/98

(57) ABSTRACT

A light-emitting device is provided. The device is with an enlarged active light-emitting region, mainly comprising a LED substrate provided with a first material layer and a second material layer on the top surface thereof in turn, and a PN junction formed between the first material layer and the second material layer naturally. Moreover, a first extended trench, allowed for passing through the second material layer and a part of the first material layer, is provided, and a first extended electrode is disposed inside the first extended trench. The electrical connection between the first extended electrode and the first electrode disposed on one part of top surface of the second material layer is made, such that the first electrode may be located at a horizontal level approximately identical to that of a second electrode equally disposed at the other part of top surface of the second material. Thus, it is possible for not only facilitating the following fabrication process, but also enlarging the active light-emitting region of the PN junction, due to the fact that a removed part of the second material layer for the formation of the first electrode required in the conventional light-emitting device is not necessary. Thereby, an effectively enhanced luminance and a prolonged service life are achieved.

### FIELD OF THE INVENTION

The present invention is related to a light-emitting device, particularly to a light-emitting device with an enlarged active light-emitting region for effectively enhancing the luminance (brightness) and prolonging the service life thereof.

### BACKGROUND

Light-emitting diodes (LEDs) have been widely used in various products, such as indicating lights, advertisement panels, traffic signal lights, vehicle lamps, display panels, communication instruments, consumer electronics, and so on, owing to features and merits including long service life, small volume, low heat, low power consumption, high response speed, no radiation, and monochromatic light.

Accordingly, for the conventional light-emitting device, such as a flat light-emitting diode shown in FIGS. 1A and 1B, a light-emitting device 10 mainly comprises a LED substrate 11 formed with a first material layer 131 and a second material layer 135, in turn, thereon. The first material layer 131 and the second material layer 135 may be combined to form an epitaxial layer 13, and a PN junction 133 with luminance effect may be formed between these two layers naturally. A part of the second material layer 136 and a part of the PN junction 137, the length in the cross section of which is at least H1, should be removed (The length of the residual active region is H2.), such that a part of the top surface of the first material layer 131 may be exposed, and a first electrode 17 is thus securely provided on a part of surface of the exposed first material layer 131, for facilitating the working current to pass through the PN junction 133 successfully. Further, a transparent contact layer (TCL) 19 may be provided on the top surface of the residual second material layer 135 for the sake of obtaining a uniform distribution of the working current. Subsequently, a second electrode 15 may be securely provided on the top surface of the transparent contact layer 19, and an electro-conductive line passing through the PN junction 133 may be then formed between the first electrode 17 and the second electrode 15, whereby a front projection light source L1 is generated.

The front projection light source L1 may be generated from the PN junction 133 in the conventional flat light-emitting device 10, though there are still disadvantages as follows:

1. The output luminous flux and luminance of the light-emitting device 10 is reduced due to the fact that the front projection light source L1 generated from the PN junction 133 may be blocked and absorbed by the second electrode 15 in part.

2. The luminance is reduced owing to the loss of a part of active light-emitting region H1, because the part of PN junction 137 should be removed for accommodating the first electrode 17.

3. The difficulty in following fabrication is raised, due to the fact that the part of second material layer 135 should be removed for accommodating the first electrode 17 such that the first electrode 17 and the second electrode 15 are not located in the same horizontal level.

4. Not only shortening the service life of the device, but also unsuitable for the high power light-emitting device may take place, owing to the high working temperature concentration in a certain area, because the part of PN junction 137 is removed to narrow the active light-emitting region, correspondingly.

For this reason, another conventional light-emitting device, shown in FIG. 2, developed by the industry is a flip chip light-emitting diode. In the fabrication of a flip chip light-emitting device 20, it is primary to invert the previously described flat light-emitting device (10). Then, the first electrode 17 and the second electrode 150 are electrically connected to a first electro-conductive line 297 and a second electro-conductive line 295, disposed on a substrate 29, by means of a first electro-conductive bump (for instance, a tin ball) 279 and a second electro-conductive bump 259, respectively. Thus, an electro-conductive passage may be formed by the first electro-conductive line 297, the first electro-conductive bump 279, the first electrode 17, and the second electrode 150, the second electro-conductive bump 259, the second electro-conductive line 295, to provide the working current for the PN junction 133, while a back projection light source L2 generated from the PN junction 133 may be projected out through the LED substrate utterly without blocked and absorbed by the second electrode 150. Thereby, an enhanced light-outputting flux and luminance is obtained.

Further, the front projection light source (L1) generated from the PN junction 133 is reflectively directed toward a correct light-outputting position to be a reflective light source 14, owing to the second electrode 150 selectively made from a light-reflective and electro-conductive material, or a light-reflecting layer 155 disposed between the epitaxial layer 13 and the second electrode 150.

A better luminous yield is obtained from the conventional flip chip light-emitting diode, though there are still structural imperfections as follows:

1. A part of the active light-emitting region is lost, and the luminance is reduced, due to the fact that the part of PN junction (137) still should be removed for accommodating the first electrode 17.

2. The difficulty in the following fabrication is increased, due to the fact that the part of second material layer (136) still should be removed for accommodating the first electrode 17, such that the first electrode 17 and the second electrode 150 are not located in the same horizontal level.

3. Not only shortening the service life of the device, but also unsuitable for the high power light-emitting device may take place, owing to the high working temperature concentration in a certain area, because the part of PN junction (137) is removed to narrow the active light-emitting region.

4. The problem in fabrication is encountered, because the first electrode 17 and the second electrode 15 are not located in an identical horizontal level, such that the volumes of the first electro-conductive bump 279 and the second electro-conductive bump 259 are also different from each other, correspondingly.

5. Not only a higher technological level, but also a significantly increased manufacturing cost may be required for the ball placement equipment and tin ball alignment technology, which are needed in the fabrication of the flip chip light-emitting device.

### SUMMARY OF THE INVENTION

Accordingly, it is the key point of the present invention to provide a novel light-emitting device, not only enhancing the luminous yield and luminance by means of an effectively uniform distribution of the working current, but also facilitating the following fabrication because a first electrode and a second electrode are located in an identical horizontal level naturally.

It is a primary object to provide a light-emitting device with an enlarged active light-emitting region, allowing for obviating the technological problems to which the above conventional light-emitting device is confronted.

It is a secondary object of the present invention to provide a light-emitting device with an enlarged active light-emitting region, having a significantly reduced area removed from a second material layer and a PN junction, so as to increase the active light-emitting region and luminous yield effectively.

It is another object of the present invention to provide a light-emitting device with an enlarged active light-emitting region, facilitating the following fabrication process by locating the first electrode and the second electrode in an identical horizontal level.

It is still another object of the present invention to provide a light-emitting device with an enlarged active light-emitting region, not only effectively prolonging the service life of the light-emitting device, but also suitable for a high power light-emitting device, by means of a larger area of the active light-emitting region.

Therefore, for achieving aforementioned objects, the primary structure according to one preferred embodiment of the present invention includes a light-emitting device with an enlarged active light-emitting region, the main structure thereof comprising a LED substrate; an epitaxial layer, including a first material layer and a second material layer, wherein the first material layer is formed on the top surface of the LED substrate, and the second material layer is then formed on the top surface of the first material layer, a PN junction being naturally formed between the first material layer and the second material layer; at least one first extended trench, allowed for passing through the second material layer and extending into a pat of the first material layer, a trench isolation layer and a first extended electrode being provided inside the first extended trench in turn, the first extended electrode and the second material layer being electrically isolated by the trench isolation layer; a first electrode, securely provided on one part of top surface of the second material layer while separated from it by a surface isolation layer, and electrically connected to the first extended electrode; and a second electrode, securely provided on the other part of top surface of the second material layer.

### BRIEF DESCRIPTION OF DRAWINGS

FIG. 1A is a structural cross section view of a conventional flat light-emitting device;

FIG. 1B is a structural top view of the conventional flat light-emitting device;

FIG. 2 is a structural cross section view of a conventional flip chip light-emitting device;

FIG. 3A is a structural cross section view of a light-emitting device according to one preferred embodiment of the present invention;

FIG. 3B is a structural top view according to the embodiment of the present invention illustrated in FIG. 3A;

FIG. 4A is a structural cross section view of a light-emitting device according to another embodiment of the present invention;

FIG. 4B is a structural top view according to the embodiment of the present invention illustrated in FIG. 4A;

FIG. 5A is a structural cross section view of a light-emitting device according to still another embodiment of the present invention;

FIG. 5B is a structural top view according to the embodiment of the present invention illustrated in FIG. 5A;

FIG. 6 is a structural cross section view of the present invention applied to the flip chip light-emitting device;

FIG. 7A is a structural cross section view according to another embodiment of the present invention;

FIG. 7B is a structural top view according to the embodiment of the present invention illustrated in FIG. 7A;

FIG. 8A is a structural cross section view according to still another embodiment of the present invention;

FIG. 8B is a structural top view according to the embodiment of the present invention illustrated in FIG. 8A;

FIG. 9A is a structural cross section view according to yet another embodiment of the present invention;

FIG. 9B is a structural top view according to the embodiment of the present invention illustrated in FIG. 9A;

FIG. 10A is a structural cross section view according to still another embodiment of the present invention;

FIG. 10B is a structural top view according to the embodiment of the present invention illustrated in FIG. 10A; and

FIG. 11 is a structural cross section view according to yet another embodiment of the present invention.

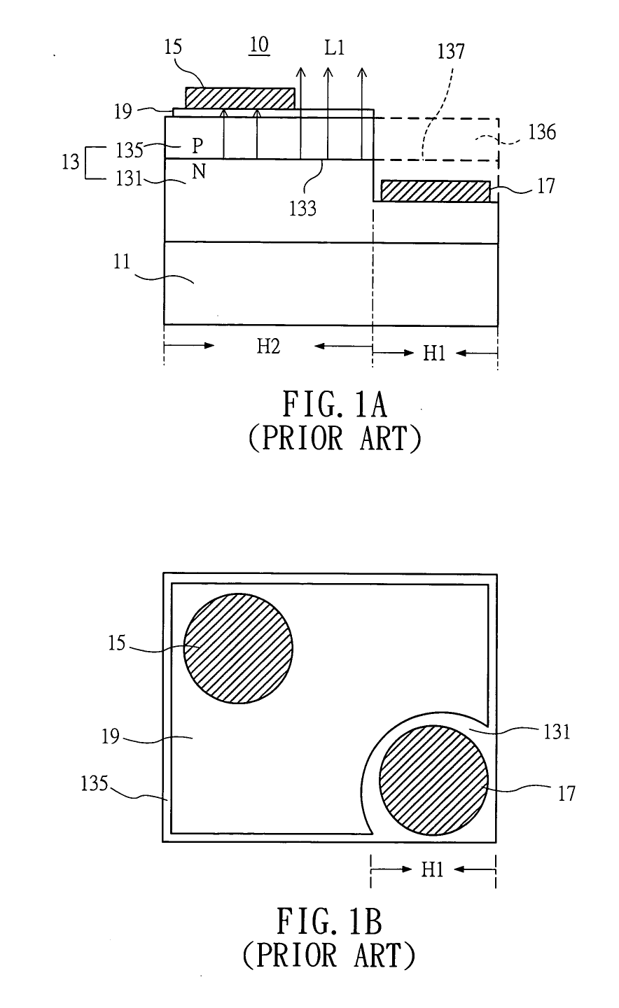

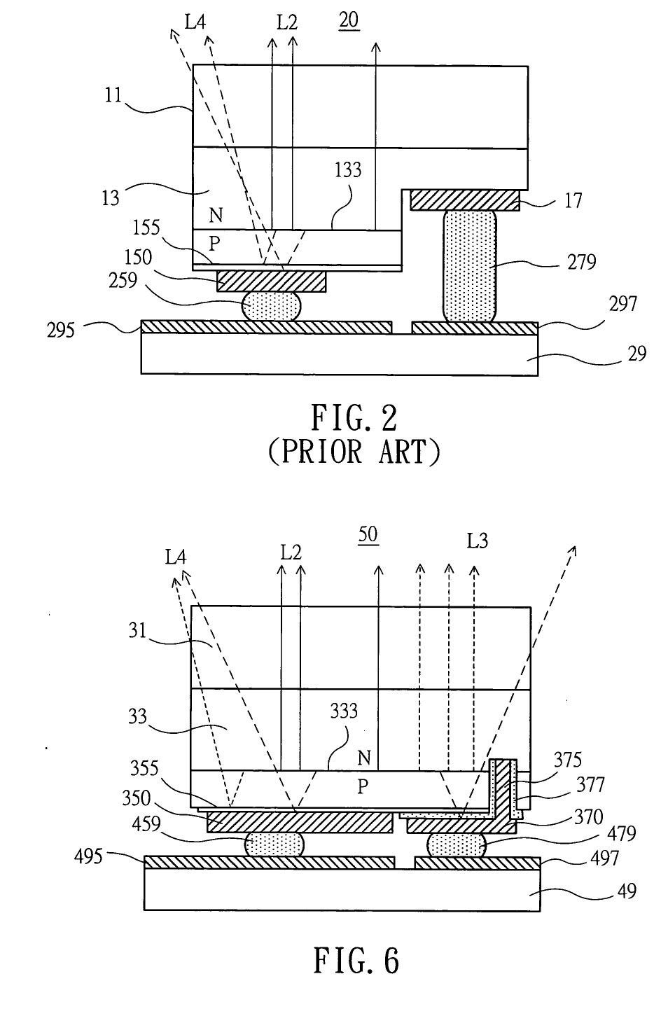

### DETAILED DESCRIPTION

The structural features and the effects to be achieved may further be understood and appreciated by reference to the presently preferred embodiments together with the detailed description.

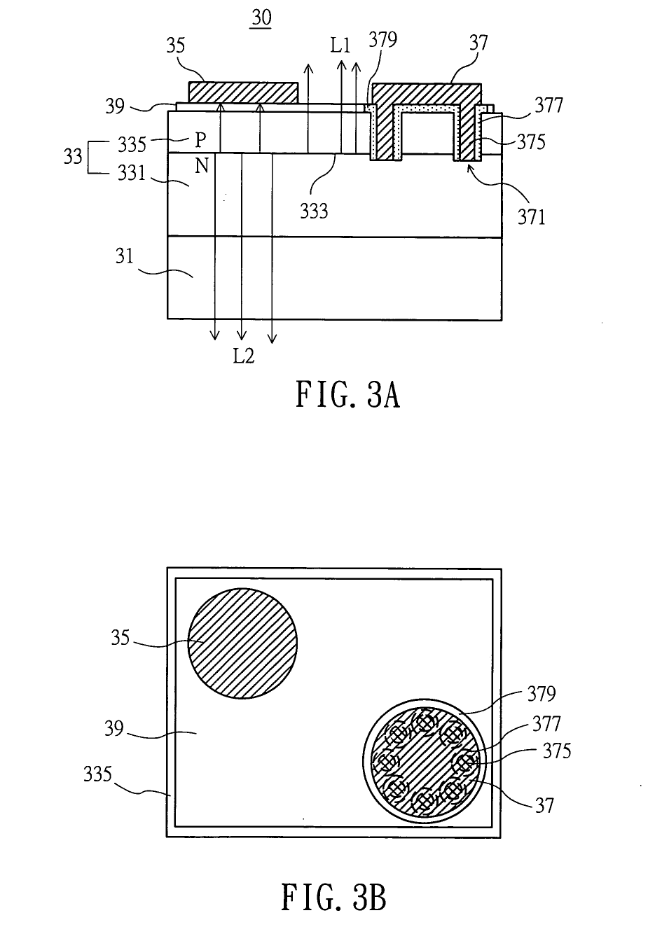

Firstly, referring to FIGS. 3A and 3B, there are shown a structural cross section view and a top view, respectively, according to one preferred embodiment of the present invention. As shown in these figures, a light-emitting device (LED) 30 of the present invention mainly comprises a LED substrate 31 formed thereon with an epitaxial layer 33, composed of a first material layer 331 and a second material layer 335 in turn. The first material layer 331 is formed onto the top surface of the LED substrate 31, and it is followed by forming the second material layer 335 onto the former, in such a way that a PN junction or light-emitting region is formed between the first material 331 and the second material 335 naturally. Thus, a flat light-emitting diode is completed. At an appropriate position in the second material layer 335, at least one first extended trench 371 is chiseled so as to pass through the whole second material layer 335 and a part of first material layer 331. Moreover, a trench isolation layer 377 and a surface isolation layer 375, each of featuring insulations is provided on the inner surface of the first extended trench 371 and the predetermined location of the first electrode 37, respectively. Within the trench isolation layer 377, a first extended electrode 375 with electro-conductive feature is further provided. The first extended electrode 375 is allowed for electrically connecting to the first electrode 37 provided at the top surface of the surface isolation layer 379, while a part of the first electrode 37 is located at a vertically extending position of the surface isolation layer 379. Furthermore, an ohm contact layer or transparent contact layer (TCL) 39 is provided on the top surface of the residual second material layer 135, and a second electrode 35 is subsequently provided on the top surface of the transparent contact layer 39, for the sake of a uniformly distributed working current.

In the present invention, the first extended trench 371 and the first extended electrode 375 are utilized for extending the electro-conductive line of the first electrode 37 to the first material layer 331, instead of chiseling or removing a large area of the second material layer (136) and PN junction (137) in the conventional structure, such that the first electrode 37 is disposed at the vertically extending position from a part of top surface of the second material layer 335. Thus, differently from the uneven relation with respect to the conventional first electrode (17) and the second electrode (15), horizontal positions, similar or equivalent to each other, are individually presented for the first electrode 37 and the second electrode 35, which may be beneficial for the subsequent fabrication process.

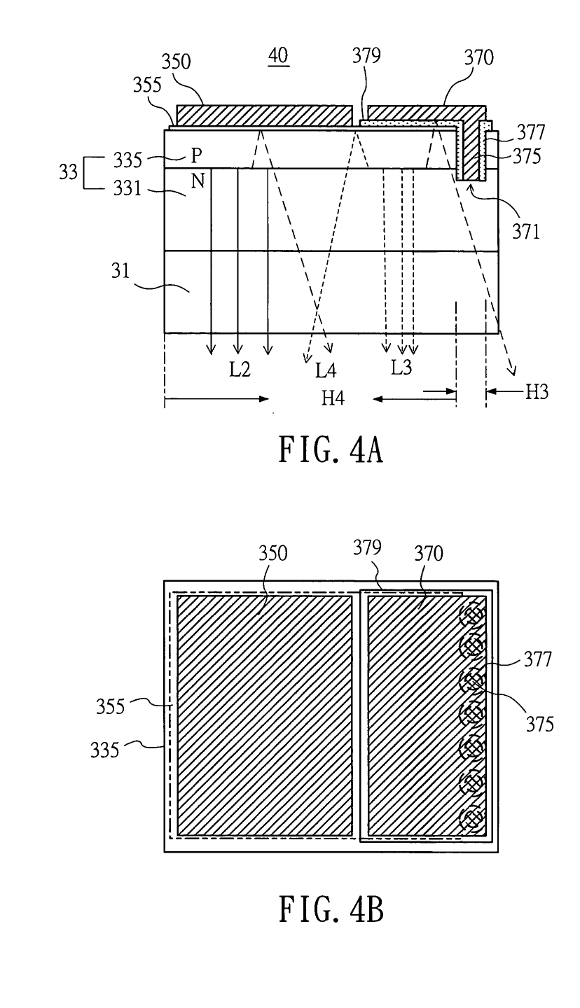

Further, referring to FIGS. 4A and 4B, there are shown a structural cross section view and a top view according to another embodiment of the present invention. As shown in these figures, the primary design thereof consists in directing the front light source of the aforementioned embodiment toward a correct light-outputting location. As such, a first electrode 370 and a second electrode 350 are allowed for covering the overall top surface of the second material layer 335 by a large area, and are formed from an electro-conductive and light-reflective material, respectively. In this case, a surface isolation layer 379 is formed between the first electrode 370 and the second material layer 335, while an electrical connection is formed between the first electrode 370 and the first material layer 331 by means of the first extended electrode 375. Further, the first extended electrode 375, the first extended trench 371, and the trench isolation layer 377 may be distributed at individual locations over the surface isolation layer 379 in various geometric modes, such as a straight line, and circle, etc., such that the objects of enhancing luminance, prolonging service life, and applying for high power light-emitting device, resulted from an uniformly distributed working current, may be obtained sufficiently.

Furthermore, the front light source, generated from the PN junction, is reflected by the first electrode 370 or the second electrode 350 to form a reflective light source L4, and then to be directed toward the correct light-outputting direction, due to the light-reflective effect inherent to the first electrode 370 and the second electrode 350. Moreover, for the further enlargement of the active region in the PN junction, the top surface of the second material layer 335 is further provided with a transparent contact layer (TCL) or ohm contact layer 355, in order for facilitating the active current to pass through the PN junction located at the vertically extending position from the first electrode 370, and for generating a back light L3. The ohm contact layer 355, of course, is made from a light-reflective material or is a light-reflecting layer itself, equally reflecting the front light source generated from the PN junction to be a reflective light source L4.

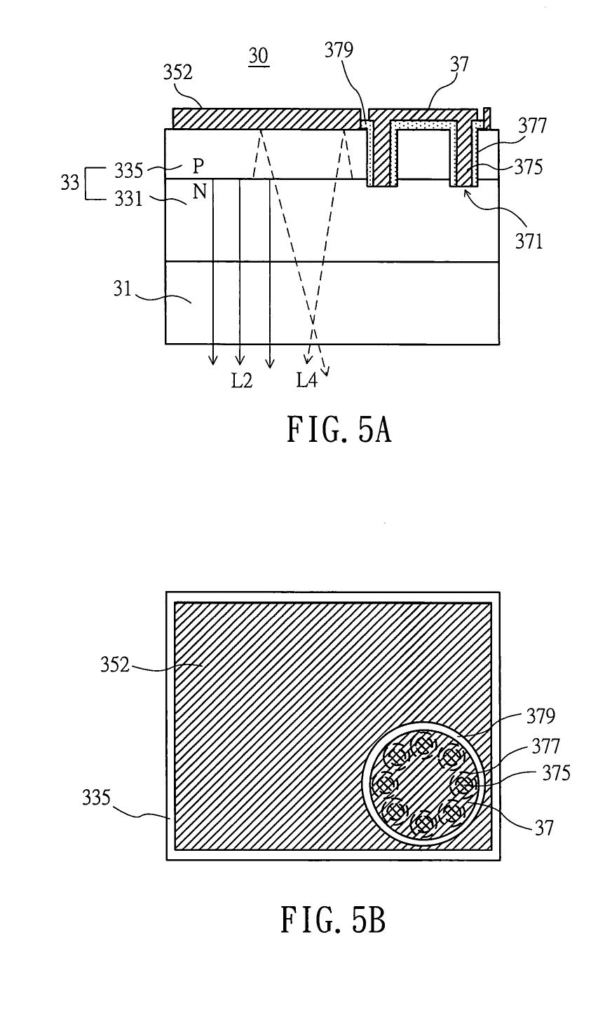

Moreover, referring to FIGS. 5A and 5B, there are shown a structural cross section view and a top view according to still another embodiment of the present invention. As shown in these figures, essentially, the most part of the top surface of the second material layer 335 is covered with the whole second electrode 352 of the embodiment illustrated in FIG. 3A, while the residual part thereof is provided with the surface isolation layer 379. Within the active region provided by the surface isolation layer 379, the first extended trench 371, the trench isolation layer 377, and the first extended electrode 375 are equally provided. Thereby, the front light source, generated from the PN junction, may be reflected by the second electrode 352 directly to be directed toward the correct light-outputting direction, and a reflective light source LA is thus obtained.

Additionally, referring to FIG. 6, there is shown a structural cross section view according to yet another embodiment of the present invention. In the embodiment, as shown in this figure, it is essential to invert the light-emitting device (40) of the aforementioned embodiment, in such a way that the first electrode 370 may be electrically connected to a first electro-conductive line 497, disposed on a substrate 49, via a first electro-conductive bump 479, while the second electrode 350 may be electrically connected to a second electro-conductive line 495, disposed on the substrate 49, via a second electro-conductive bump 459. Thereby, a flip chip light-emitting diode is thus formed.

The first electro-conductive bump 479 and the second electro-conductive bump 459, of course, may be made from a solder material, tin ball, metal-containing substance, or any electro-conductive substance, which may be featuring electro-conductivity. Moreover, the substrate 49 is made from a material selected from the group consisting of a ceramics, glass, AlN, SiC, Al₂O₃, epoxy, urea resin, plastic, diamond, BeO, BN, circuit board, printed circuit board, PC board, and metal-containing compound.

The first electro-conductive bump 479 and the second electro-conductive bump 459 required for the subsequent process may have the same volume, owing to similar or equivalent horizontal locations occupied with the first electrode 370 and the second electrode 350 in the light-emitting device 50 of the present invention. In this case, not only facilitating the fabrication, but also enhancing the working reliability of the element, due to the fact that the acting forces at two sides provided by the first electro-conductive bump 479 and the second electro-conductive bump 459, respectively, are under an equivalent state without biasing the light-emitting device 50. Thereby, a relatively enhanced working reliability of the element is achieved.

Moreover, a back projection light source L3 may be also added except for the common back projection light source L2 and reflective light source 14 in the conventional flip chip light-emitting diode structure, due to the fact that an excessive active region is never removed by a light-emitting region of PN junction 333 of the light-emitting device 50. Thereby, not only the increased luminance, but also the relatively reduced current density of the working current and the working temperature in a certain area owing to an enlarged active light-emitting region may be achieved, further resulting in an effectively prolonged service life of the light-emitting device.

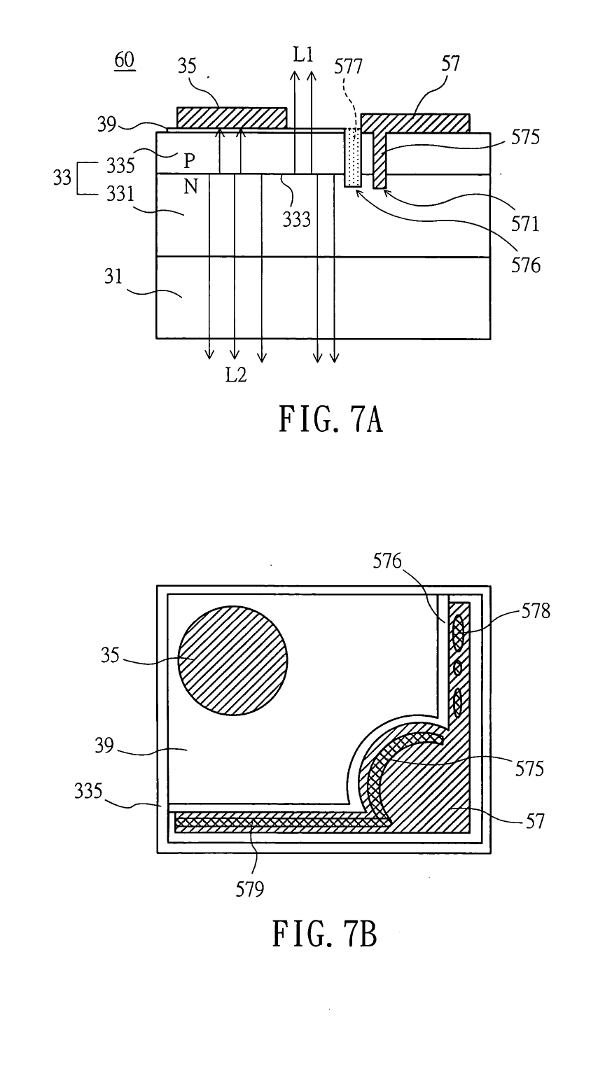

Next, referring to FIGS. 7A and 7B, there are shown a structural cross section view and a top view according to another embodiment of the present invention. In this embodiment, as shown in these figures, there is mainly an isolation trench 576, allowed for passing through the second material layer 335 and a part of the first material layer 331, chiseled on the second material layer 335 of the light-emitting device 60 at a predetermined position adjacent to the first electrode 57. An isolation layer 577 capable of enhancing the isolation effect may be further provided inside the isolation trench 576 selectively in place of the trench isolation layer 377 or surface isolation layer 379 in the aforementioned embodiment. Again, a first extended trench 571 and a first extended electrode 575 may be provided at one side of the isolation trench 576, while the first extended electrode 575 may be electrically connected to the first electrode 57 disposed on a part of the surface of the second material layer 335.

In this embodiment, a transparent contact layer (TCL) or ohm contact layer 39 may be provided on a part of the surface of the second material layer 335, and the second electrode 35 may be further securely provided on a part of the surface of this transparent contact layer (TCL) or ohm contact layer 39 in turn, for the uniform distribution of the working current. Furthermore, the isolation trench 576 may be provided in the second material layer 335 in place, and along the side of the isolation trench 576, the first electrode 57 is disposed. On a part of this first electrode 57, there may be extendingly provided with at least one second extended electrode 578 or third extended electrode 579 allowed for passing through the second material layer 335 and a part of the first material layer 331, in such a way that the working current may be distributed more uniformly. In this embodiment, the isolation trench 576 is mainly used for the object of isolating the first electrode 57 and the second electrode 35, such that both of them may be disposed in the same horizontal level on parts of the surface of the second material layer 335 to be beneficial for the following fabrication process.

The second extended electrode 578 or the third extended electrode 579 may be, of course, presented as a shape selected from the group consisting of a point, bar, ring, circle, rectangle, straight line, half-ring, and the combination thereof. In this embodiment, for example, the second extended electrode 578 is presented as a point, while the third extended electrode 579 is presented as a bar-shaped mode covering the side as a whole.

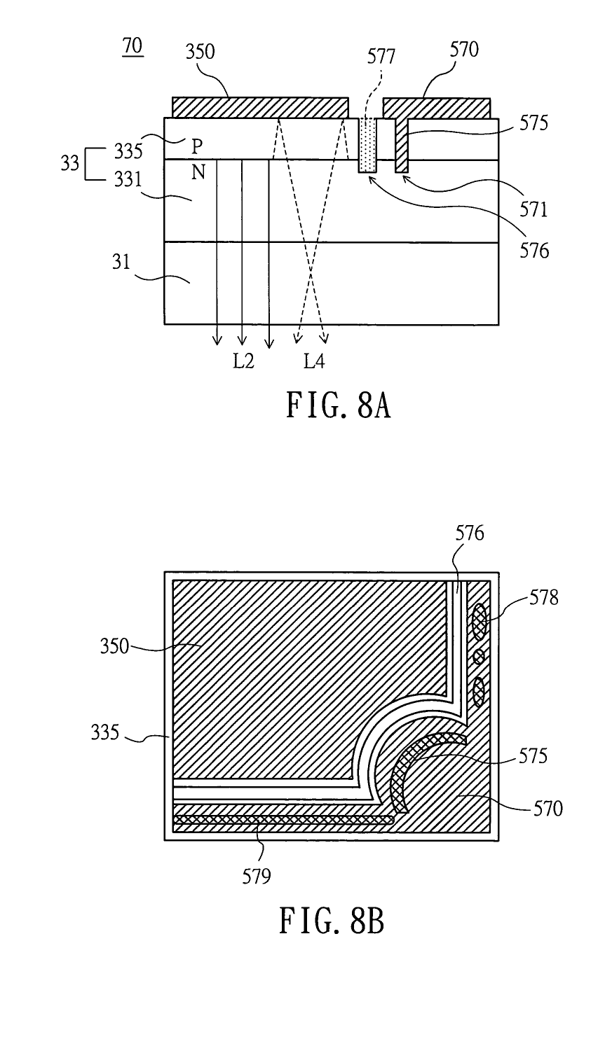

Additionally, referring to FIGS. 8A and 8B, there are shown a structure cross section view and a structural top view, respectively, according to still another embodiment of the present invention. As illustrated in these figures, it is essential to cover the top surface of the second material layer 335 by a large area by means of the first electrode 570 and the second electrode 350 illustrated in the aforementioned embodiment, in which an electrical connection is formed between the first electrode 570 and the first material layer 331 by means of the first extended electrode 575. Further, the first extended electrode 575, the second extended electrode 578, and the third extended electrode 579 are distributed at one side of the second material layer 335 in various geometrical modes, such as a straight line or circle, and electrically connected to the first electrode 570.

Of course, either the light-reflective effect provided by the first electrode 570 and the second electrode 350, or the light-reflective layer, ohm contact layer or transparent contact layer 355 disposed between the second material layer 335 and the second electrode 350, may be equally used for reflecting the front light source generated from the PN junction to form a reflective light source L4 to be beneficial for the enhancement of the luminance.

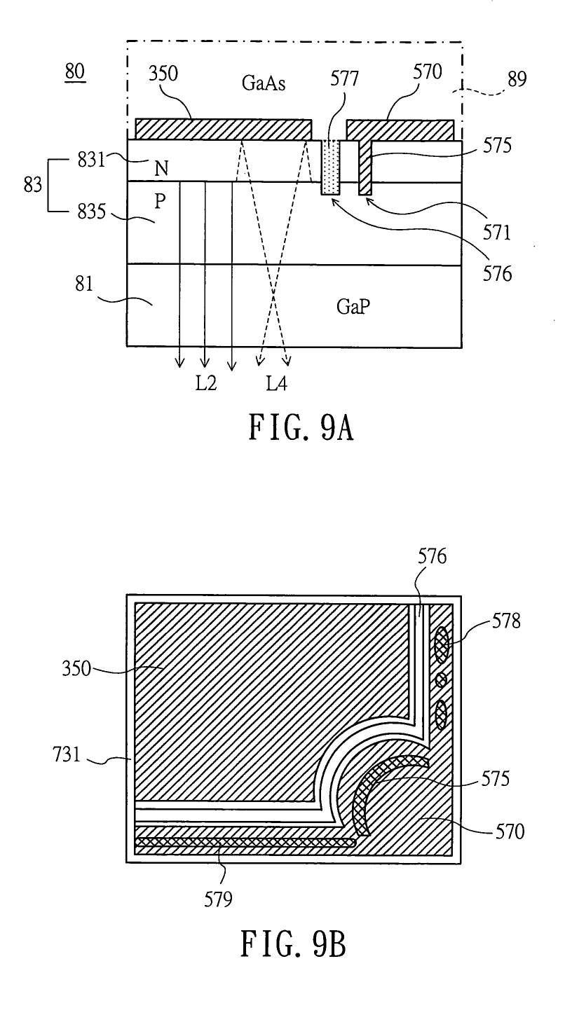

Furthermore, referring to FIGS. 9A and 9B, there are shown a structural cross section view and a structural top view, respectively, according to yet another embodiment of the present invention. In this embodiment, as illustrated in these figures, the scope of the present invention is mainly applied to ternary (AlGaAs) or quaternary (AlGaInP) light-emitting device. On a semiconductor substrate 89, such as GaAs substrate, there is grown an epitaxial layer 83, which is made from what selected from the group consisting of a ternary and a quaternary compound. Further, on the top surface of the second material layer 835, there is formed with a transparent substrate 81, such as GaP substrate, glass, sapphire, SiC, GaAsP, ZnSe, ZnS, ZnSSe, and quartz. On the other hand, the opaque GaAs substrate 89, allowed for absorbing the projection light source, may be removed.

Next, at the surface of the first material layer 831, there is chiseled the isolation trench 576 and the first isolation trench 571 allowed for passing through the first material layer 831 and a part of the second material layer 835. Inside the isolation trench 576, the isolation layer 577 is selectively provided as desired; while inside the first isolation trench 571, the first extended electrode 575 should be provided, and may be electrically connected to the first electrode 570 disposed on one part of the surface of the first material layer 831. The second electrode 350, disposed on the other part of the surface of the first material layer 831, may be separated from the first electrode 570 by the isolation trench 576, while an electro-conductive passage may be formed between theses two electrodes.

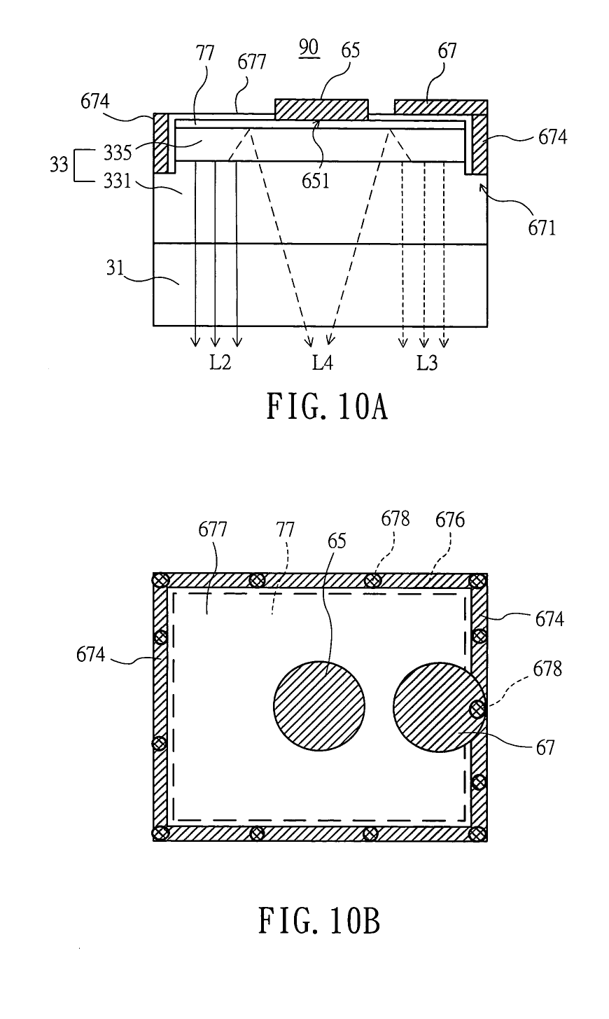

Subsequently, referring to FIGS. 10A and 10B, there are shown a structural cross section view and a structural top view, respectively, according to still another embodiment of the present invention. In this embodiment, as illustrated in these figures, a third extended trench (or referred to as first extended trench) 671, allowed for passing through the second material layer 335 and a part of the first material layer 331, may be chiseled around the periphery of a light-emitting device 90 firstly. Moreover, a transparent contact layer, ohm contact layer, or light-reflecting layer 77 with electro-conductive or light-reflective effect is disposed on the top surface of the second material layer 335, and then an isolation layer 677 is provided on the periphery of the light-reflecting layer 77 and second material layer 355. A second extended trench 651 is chiseled in the isolation layer 677 in place, such that a second electrode 65 may be electrically connected to the second material layer 335 directly or via the light-reflecting layer 77. Around the periphery of the second material layer 335 and separated from that second electrode by the isolation layer 677, a first perimeter electrode 674, allowed for electrically connected to a first electrode 67, is disposed. As such, the object of uniformly distributing the working current, enlarging the active light-emitting region, and locating the first electrode 67 and the second electrode 65 in an identical horizontal level may be achieved.

On the periphery of the second material layer 335, of course, at least one point-type fourth extended electrode 678 may be also used to replace the ring-type annular first perimeter electrode 674. A surface electrode 676 is required for the electrical connection between each fourth extended electrode 678 and the first electrode 67.

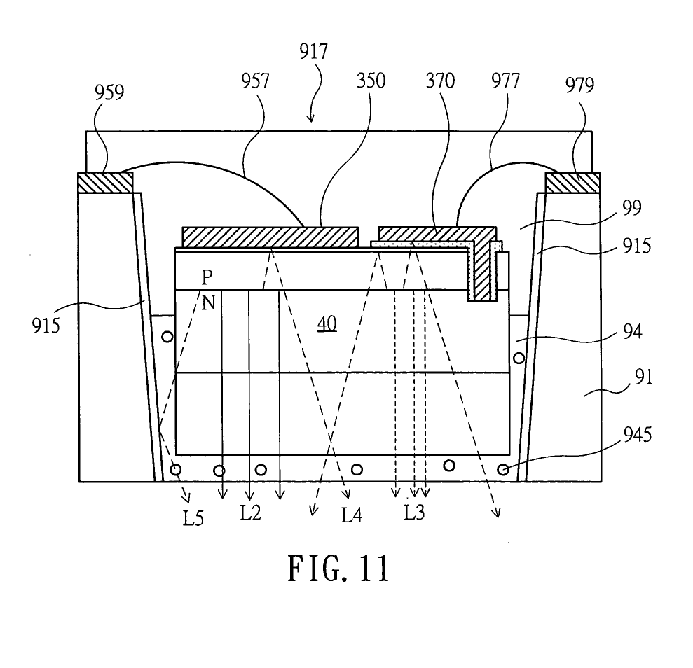

Finally, referring to FIG. 11, there is shown a structural cross section according to yet another embodiment of the present invention. In this embodiment, as illustrated in this figure, it is essential to put the aforementioned light-emitting device 40 (as shown in FIG. 4A) into an accommodating trench 917 chiseled inside a substrate 91, and to fix it by means of a transparent layer 40 or heat-dissipating layer 99. The electrical connection between the first electrode 370 of the light-emitting device 40 and a first electro-conductive line 979 disposed on the substrate 91 is made by means of a first electro-conductive lead 977. For the same reason, the second electrode 350 is electrically connected to a second electro-conductive line 959 disposed at the other side of the substrate 91 by means of a second electro-conductive lead 957. The back projection light sources L2, L3 may be generated by the effect of the PN junction, resulted from the first electro-conductive line 979, the first electro-conductive lead 977, the first electrode 370, and the second electrode 350, the second electro-conductive lead 957, the second electro-conductive line 959, while the reflective light source L4 is formed by directing the front projection light source toward a correct light-outputting direction via the first electrode 370, the second electrode 350, or the light-reflecting layer. Thereby, a luminous yield comparable to that of the flip chip light-emitting diode may be achieved by the traditional fabrication process for light-emitting device, without the need for ball placement equipment or tin ball alignment technology. Thus, a simplified fabrication process and a significantly reduced manufacturing cost may be obtained.

Further, the substrate 91 may be made from what selected from the group consisting of a ceramics, glass, AIN, SiC, Al₂O₃, epoxy, urea resin, plastic, diamond, BeO, BN, circuit board, printed circuit board, PC board, and metal-containing compound, and the accommodating trench 917 thereof may be designed as a ring, rectangle, or taper mode. Moreover, a light-reflective layer 915 may be provided on the periphery of the accommodating trench 917, in such a way that a reflective light source L5 may be obtained except for the normal reflective light sources L2, L3, L4, in order for effectively enhancing the luminance.

Further, within the transparent layer 94, there is provided a color transformation layer 945 which, used for the change of the wavelength and color of the reflective colorful light, is composed of what selected from the group consisting of fluorescent substance, phosphorescent substance, and the combination thereof.

Furthermore, the high working temperature generated when the light-emitting device 40 operates may be conducted outside of the light-emitting device 40 via the heat-dissipating layer 99, featuring heat-dissipating function and covering the periphery of the PN junction, resulting in suitable for the high power light-emitting device.

To sum up, it should be understood that the present invention is related to a light-emitting device, particularly to a light-emitting device with an enlarged active light-emitting region for effectively enhancing the luminance and prolonging the service life thereof.

The foregoing description is merely one embodiment of present invention and not considered as restrictive. All equivalent variations and modifications in process, method, feature, and spirit in accordance with the appended claims may be made without in any way from the scope of the invention.

### LIST OF REFERENCE SYMBOLS

10 Light-emitting device
11 LED substrate
13 epitaxial layer
131 first material layer
133 PN junction
135 second material layer
136 removed second material layer
137 removed PN junction
15 second electrode
150 second electrode
155 light-reflective layer
17 first electrode
19 transparent contact layer
20 flip chip light-emitting device
259 second electro-conductive bump
279 first electro-conductive bump
29 substrate
295 second electro-conductive layer
297 first electro-conductive layer
30 light-emitting device
31 LED substrate
33 epitaxial layer
331 first material layer
333 PN junction
335 second material layer
35 second electrode
350 second electrode
352 second electrode
355 ohm contact layer
37 first electrode
370 first electrode
371 first extended trench
375 first extended electrode
377 trench isolation layer
379 surface isolation layer
40 flip chip light-emitting device
459 second electro-conductive bump
479 first electro-conductive bump
49 substrate
495 second electro-conductive layer
497 first electro-conductive layer
50 light-emitting device
57 first electrode
571 first extended trench
575 first extended electrode
576 isolation trench
577 isolation layer
578 second extended electrode
579 third extended electrode
60 light-emitting device
65 second electrode
651 second extended trench
67 first electrode
671 third extended trench
674 first perimeter electrode
676 surface electrode
677 isolation layer
678 fourth extended electrode
70 light-emitting device
77 light-reflecting layer
80 light-emitting device
81 transparent substrate
83 epitaxial layer
831 first material layer
835 second material layer
89 GaAs substrate
91 substrate
915 light-reflecting layer
917 accommodating trench
945 color transformation layer
957 second electro-conductive lead
959 second electro-conductive line
977 first electro-conductive lead
979 first electro-conductive line
99 heat-dissipating layer

1. A light-emitting device with an enlarged active light-emitting region, comprising:
a LED substrate;
an epitaxial layer, including a first material layer and a second material layer, wherein said first material layer is formed on the top surface of said LED substrate, and said second material layer is then formed on the top surface of said first material layer, a light-emitting region naturally included between said first material layer and said second material layer;
at least one first extended trench, allowed for passing through said second material layer and extending into a pat of said first material layer, a trench isolation layer and a first extended electrode being provided inside said first extended trench in turn, said first extended electrode and said second material layer being electrically isolated by said trench isolation layer;
a first electrode, securely provided on one part of top surface of said second material layer while separated from it by a surface isolation layer, and electrically connected to said first extended electrode; and
a second electrode, securely provided on the other part of top surface of said second material layer.

2. The light-emitting device according to claim 1, wherein said first electrode and said second electrode are located in approximately horizontal levels.

3. The light-emitting device according to claim 1, wherein said first extended electrode is located at a position vertically extending from said first electrode.

4. The light-emitting device according to claim 1, wherein between said second electrode and said second material layer, there is further provided with what selected from the group consisting of a transparent contact layer, ohm contact layer, light-reflecting layer, and the combination thereof.

5. The light-emitting device according to claim 1, wherein between said surface isolation layer and said second material layer, further provided with what selected from the group consisting of a transparent contact layer, ohm contact layer, light-reflecting layer, and the combination thereof.

6. The light-emitting device according to claim 1, further comprising a substrate provided with a first electro-conductive layer and a second electro-conductive layer, respectively, on the top surface thereof, wherein said first electro-conductive layer is electrically connected to said first electrode by a first electro-conductive bump, and said second electro-conductive layer is electrically connected to said second electrode by a second electro-conductive bump.

7. The light-emitting device according to claim 6, wherein said light-emitting device is a flip chip light-emitting diode.

8. The light-emitting device according to claim 6, wherein said substrate is made from what selected from the group consisting of a ceramics, glass, AIN, SiC, Al₂O₃, epoxy, urea resin, plastic, diamond, BeO, BN, circuit board, printed circuit board, PC board, metal-containing compound, and the combination thereof.

9. The light-emitting device according to claim 1, wherein said light-emitting device is a flat light-emitting diode.

10. The light-emitting device according to claim 1, wherein said LED substrate is selected from the group consisting of a GaP substrate, glass, sapphire, SiC, GaAsP, ZnSe, ZnS, ZnSSe, quartz, and the combination thereof.

11. The light-emitting device according to claim 10, wherein said epitaxial layer is made from a material presented as a mode selected from the group consisting of a ternary mode, quaternary mode, and the combination thereof.

12. The light-emitting device according to claim 1, further comprising a substrate having an accommodating trench chiseled therein for accommodating said light-emitting device, wherein said first electrode is electrically connected to a first electro-conductive line disposed on said substrate by a first electro-conductive lead, and said second electrode is electrically connected to a second electro-conductive line disposed on said substrate by a second electro-conductive lead.

13. The light-emitting device according to claim 12, wherein within said accommodating trench, there is further provided with a transparent layer around the periphery of said light-emitting device.

14. The light-emitting device according to claim 13, wherein within said transparent layer 94, further provided a color transformation layer made from what selected from the group consisting of fluorescent substance, phosphorescent substance, and the combination thereof.

15. The light-emitting device according to claim 12, wherein within said accommodating trench, further provided with a heat-dissipating layer around the periphery of said light-emitting device.

16. The light-emitting device according to claim 12, wherein said substrate is made from what selected from the group consisting of a ceramics, glass, AIN, SiC, Al₂O₃, epoxy, urea resin, plastic, diamond, BeO, BN, circuit board, printed circuit board, PC board, metal-containing compound, and the combination thereof.

17. The light-emitting device according to claim 12, wherein said accommodating trench is presented as a mode selected from the group consisting of a taper, circle, and ring.

18. The light-emitting device according to claim 12, wherein a light-reflective layer is further provided on the inner surface of said accommodating trench.

19. The light-emitting device according to claim 1, wherein said first extended trench is provided around the periphery of said first electrode.

20. The light-emitting device according to claim 19, wherein at least one first extended electrode is provided inside said first extended trench, each extended electrode electrically connected to said first electrode by means of a surface electrode disposed on the top surface of the former.

21. The light-emitting device according to claim 20, wherein said first extended electrode is presented as a shape selected from the group consisting of a point, bar, ring, circle, rectangle, straight line, half-ring, and the combination thereof.

22. The light-emitting device according to claim 1, wherein said first electrode and second electrode are allowed for covering a vertically extending position of the top surface of said second material layer as a whole, and made from an electro-conductive and light-reflective material, respectively.

23. The light-emitting device according to claim 1, wherein said first extended trench is provided around the periphery of said second material and allowed for passing through a part of said first material layer, said trench isolation layer and said first extended electrode provided inside said first extended trench in turn.

24. The light-emitting device according to claim 23, wherein said first extended electrode is a perimeter electrode.

25. The light-emitting device according to claim 23, wherein a second extended trench is chiseled at said surface isolation layer so as to expose one part of top surface of said second material layer, and said second electrode is fixed inside said second extended trench and on the other part of top surface of said second material layer.

26. A light-emitting device with an enlarged active light-emitting region, the main structure thereof comprising:
a LED substrate;
an epitaxial layer, including a first material layer and a second material layer, wherein said first material layer is formed on the top surface of said LED substrate, and said second material layer is then formed on the top surface of said first material layer, a light-emitting region naturally included between said first material layer and said second material layer;
a second electrode, securely provided on one part of top surface of said second material layer;
a first electrode, securely provided on the other part of top surface of said second material layer;
at least one extended trench provided at said first electrode in proper place, each extended trench passing through said second material layer and a pat of said first material layer, at least one extended electrode electrically connected to said first electrode being provided inside said extended trench; and
at least one isolation trench, provided between said first electrode and said second electrode, and allowed for passing through said second material layer and a part of said first material layer.

27. The light-emitting device according to claim 26, wherein said first electrode and said second electrode are located in approximately horizontal levels.

28. The light-emitting device according to claim 26, wherein between said first material layer and said first electrode, further provided with what selected from the group consisting of a transparent contact layer, ohm contact layer, light-reflective layer, and the combination thereof.

29. The light-emitting device according to claim 26, further comprising a substrate provided with a first electro-conductive layer and a second electro-conductive layer, respectively, on the top surface thereof, wherein said first electro-conductive layer is electrically connected to said first electrode by a first electro-conductive bump, and said second electro-conductive layer is electrically connected to said second electrode by a second electro-conductive bump.

30. The light-emitting device according to claim 29, wherein said substrate is made from what selected from the group consisting of a ceramics, glass, AIN, SiC, Al₂O₃, epoxy, urea resin, plastic, diamond, BeO, BN, circuit board, printed circuit board, PC board, metal-containing compound, and the combination thereof.

31. The light-emitting device according to claim 29, wherein said light-emitting device is a flip chip light-emitting diode.

32. The light-emitting device according to claim 26, further comprising a substrate having an accommodating trench chiseled therein for accommodating said light-emitting device, wherein said first electrode is electrically connected to a first electro-conductive line disposed on said substrate by means of a first electro-conductive lead, and said second electrode is electrically connected to a second electro-conductive line disposed on said substrate by means of a second electro-conductive lead.

33. The light-emitting device according to claim 26, wherein said extended trench is presented as a shape selected from the group consisting of a point, bar, ring, circle, rectangle, straight line, half-ring, and the combination thereof.

34. The light-emitting device according to claim 26, wherein an isolation layer is further provided inside said isolation trench.

35. The light-emitting device according to claim 26, wherein said first electrode and second electrode are allowed for covering an overall top surface of said second material layer, and made from an electro-conductive and light-reflective material, respectively.

36. The light-emitting device according to claim 26, wherein between said first material layer and said first electrode, further provided with what selected from the group consisting of a transparent contact layer, ohm contact layer, light-reflective layer, and the combination thereof.

37. The light-emitting device according to claim 26, wherein said LED substrate is selected from the group consisting of a GaP substrate, glass, sapphire, SiC, GaAsP, ZnSe, ZnS, ZnSSe, quartz, and the combination thereof.

38. The light-emitting device according to claim 37, wherein said epitaxial layer is made from a material presented as a mode selected from the group consisting of a ternary mode, quaternary mode, and the combination thereof.

39. The light-emitting device according to claim 26, wherein said extended trench is provided around the periphery of said second material and allowed for passing through a part of said first material layer, said extended electrode being provided inside said extended trench in turn.

40. The light-emitting device according to claim 39, wherein said extended electrode is a perimeter electrode.

41. The light-emitting device according to claim 39, wherein a surface isolation layer is further provided on the surface of said second material layer, a second extended trench being chiseled at said surface isolation layer so as to expose one part of top surface of said second material layer, and said second electrode fixed inside said second extended trench and on the other part of top surface of said second material layer.
